(19) United States
(12) Patent Application Publication
(10) Pub. No.: US 2025/0287685 A1
(43) Pub. Date: Sep. 11, 2025

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventor: Toshiaki SAKATA, Matsumoto-city (JP)

(21) Appl. No.: 19/218,346

(22) Filed: May 25, 2025

Related U.S. Application Data
(63) Continuation of application No. PCT/JP2024/014745, filed on Apr. 11, 2024.

(30) Foreign Application Priority Data
Jun. 22, 2023 (JP) 2023-102280

(51) Int. Cl. H10D 84/80; H10D 1/00; H10D 1/40; H10D 8/00; H10D 8/01; H10D 12/00; H10D 12/01; H10D 62/53; H10D 89/60

(52) U.S. Cl. CPC H10D 84/811; H10D 1/025; H10D 1/40; H10D 8/045; H10D 8/411; H10D 12/038; H10D 12/481; H10D 62/53; H10D 89/611; H10D 89/911

(57) ABSTRACT

Provided is a semiconductor device including: a transistor portion; a current sensing portion which detects a current flowing through the transistor portion; a gate pad which is provided above a semiconductor substrate; and a resistance adjustment portion which is electrically connected to the gate pad and adjusts gate resistances of the transistor portion and the current sensing portion, in which the resistance adjustment portion includes a main adjustment portion which is electrically connected to a gate conductive portion of the transistor portion, and a sense adjustment portion which is electrically connected to a gate conductive portion of the current sensing portion, and each of the main adjustment portion and the sense adjustment portion includes a diode element portion including a plurality of diodes provided in anti-parallel and a resistance portion which is connected to the diode element portion.

The contents of the following patent application(s) are incorporated herein by reference:
NO. 2023-102280 filed in JP on Jun. 22, 2023
NO. PCT/JP2024/014745 filed in WO on Apr. 11, 2024.

### BACKGROUND

### 1. Technical Field

The present invention relates to a semiconductor device and a method for manufacturing

the semiconductor device.

### 2. Related Art

Patent Document 1 discloses a semiconductor device “including a main IGBT cell and a sense IGBT cell connected in parallel with each other”.
Prior Art Documents
Patent Documents
Patent Document 1: Japanese Patent Application Publication No. 2019-149558
Patent Document 2: Japanese Patent No. 5591213
Patent Document 3: Japanese Patent No. 6102394

### BRIEF DESCRIPTION OF THE DRAWINGS

FIG. 1A illustrates an example of a top view of a semiconductor device 100.

FIG. 1B illustrates an example of an enlarged view of an upper surface of the semiconductor device 100.

FIG. 1C illustrates an example of a cross section a-a′ in FIG. 1B.

FIG. 2A illustrates an example of a circuit configuration of the semiconductor device 100. FIG. 2B illustrates a modification of the circuit configuration of the semiconductor device 100.

FIG. 3A illustrates waveforms of a collector current Ic′ and a sense current Ise′ flowing through a semiconductor device of a comparative example.

FIG. 3B illustrates waveforms of a collector current Ic and a sense current Ise flowing through the semiconductor device 100.

FIG. 4A illustrates an example of an enlarged view of the upper surface around a current sense pad 190 and a gate pad 150.

FIG. 4B illustrates an example of a cross section b-b′ in FIG. 4A.

FIG. 5A illustrates an example of a cross section c-c′ in FIG. 4A.

FIG. 5B illustrates an example of a top view of a diode element portion 61.

FIG. 5C illustrates an example of a top view of a resistance portion 62.

FIG. 6A illustrates an example of a cross section d-d′ in FIG. 4A.

FIG. 6B illustrates an example of a cross section e-e′ in FIG. 4A.

FIG. 7A illustrates an example of a method for manufacturing the semiconductor device 100 including a resistance adjustment portion 60.

FIG. 7B illustrates an example of a method for manufacturing the semiconductor device 100 including the resistance adjustment portion 60.

FIG. 8 illustrates a modification of the cross section c-c′ in FIG. 4A.

FIG. 9A illustrates a modification of the cross section c-c′ in FIG. 4A.

FIG. 9B illustrates a modification of the cross section c-c′ in FIG. 4A.

FIG. 10 illustrates an example of a top view of the resistance adjustment portion 60.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention.

Herein, one side of a semiconductor substrate in a direction parallel to a depth direction of the semiconductor substrate is referred to as “front” or “upper”, and an opposite side is referred to as “back” or “lower”. One surface of two principal surfaces of a substrate, a layer or another member is referred to as an upper surface, and another surface is referred to as a lower surface. A direction indicated by “front”, “upper”, “back”, or “lower” is not limited to a gravitational direction or a direction of implementing the semiconductor device.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When a Z axis direction is described without describing the signs, it means that the direction is parallel to a +Z axis and a −Z axis. As used herein, when seen from the +Z axis direction, it may also be referred to “top view”.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. Note that conductivity types of respective doping regions may be of opposite polarities, respectively. Further, in the present specification, a description of a P+ type or an N+ type means a higher doping concentration than that of the P type or the N type, and a description of a P− type or an N− type means a lower doping concentration than that of the P type or the N type.

In the present specification, the doping concentration indicates a concentration of an impurity activated as a donor or an acceptor. Herein, in some cases, a concentration difference between a donor and an acceptor may be a higher concentration of the two, the donor or the acceptor. The concentration difference can be measured by a capacitance-voltage profiling method (CV method). Also, a carrier concentration measured by Spread Resistance (SR) measurement method may be a concentration of a donor or an acceptor. In addition, in a case where a concentration distribution of a donor or an acceptor has a peak, the peak value may be a concentration of a donor or acceptor in the region. In a region where donors or acceptors are present, when concentration of the donors or the acceptors is substantially uniform or the like, an average value of donor concentration or acceptor concentration in this region may be set as donor concentration or acceptor concentration.

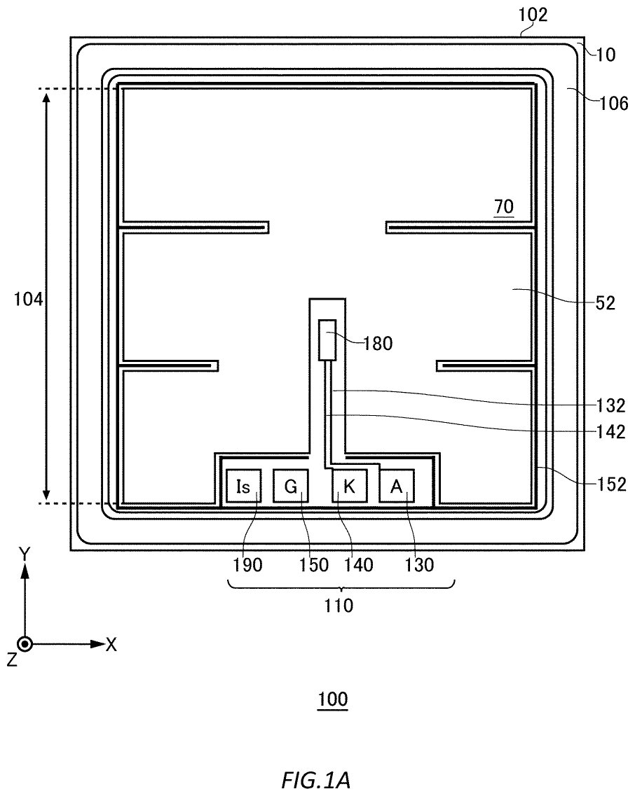

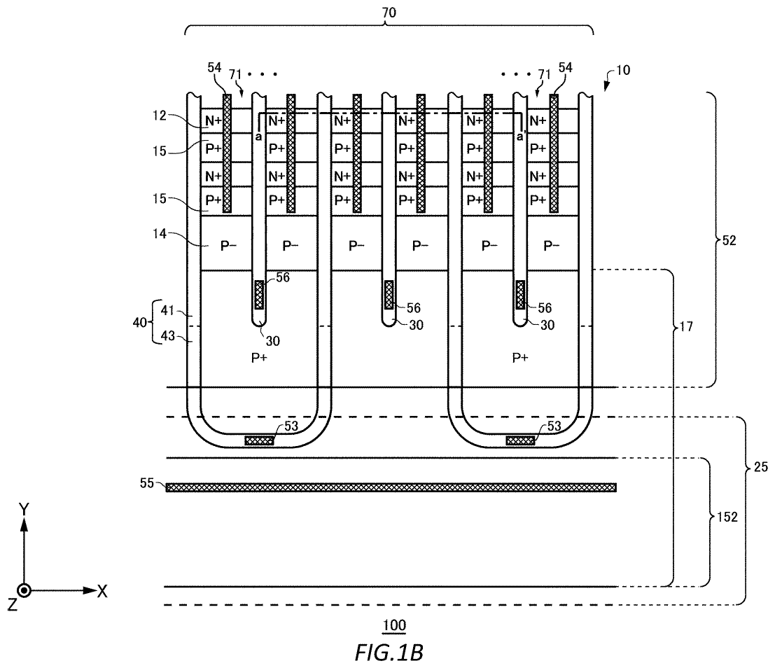

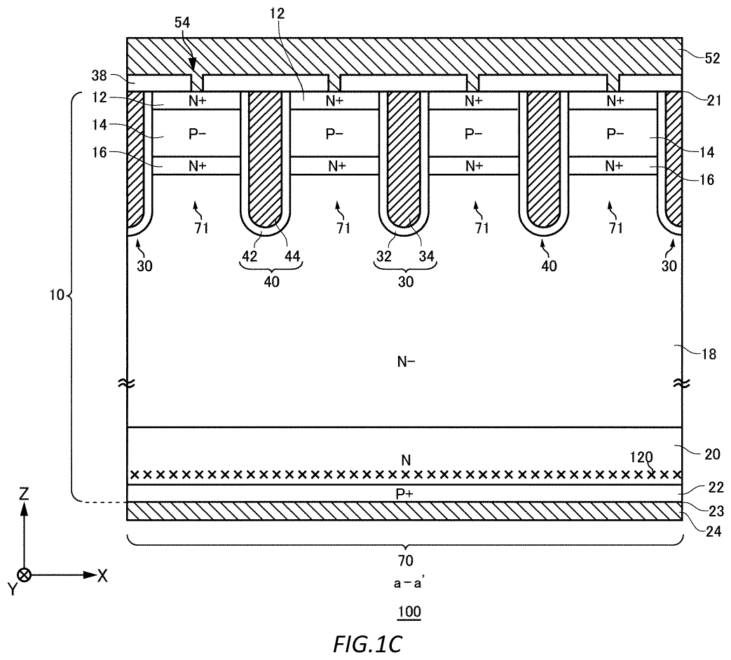

FIG. 1A illustrates an example of a top view of a semiconductor device 100. The semiconductor device 100 is a semiconductor chip including a transistor portion 70. The semiconductor device 100 includes a temperature sensing portion 180, and may be mounted on a module such as an intelligent power module (IPM).

The transistor portion 70 includes a transistor such as an insulated gate bipolar transistor (IGBT). The transistor portion 70 may be another transistor such as a MOSFET. The semiconductor device 100 may be a reverse conducting IGBT (RC-IGBT) having a diode such as a free wheel diode (FWD) on a same chip.

A semiconductor substrate 10 may be a silicon substrate, may be a silicon carbide substrate, or may be a nitride semiconductor substrate such as gallium nitride, or the like. The semiconductor substrate 10 in the present example is the silicon substrate. The semiconductor substrate 10 includes an active portion 104 and an outer peripheral portion 106. Note that when merely referred to as the top view in the present specification, it means that the semiconductor substrate 10 is viewed from an upper surface side. As will be described later, the semiconductor substrate 10 includes a front surface 21 and a back surface 23.

The transistor portion 70 is a region obtained by projecting a collector region provided on a lower surface side of the semiconductor substrate 10 onto an upper surface of the semiconductor substrate 10. The collector region is of a second conductivity type. The collector region is of P+type as an example.

Note that the transistor portion 70 in the present example has a trench portion extending in a Y axis direction. However, the transistor portion 70 may have a trench portion extending in an X axis direction.

The active portion 104 includes the transistor portion 70. The active portion 104 is a region in which a main current flows between the upper and lower surfaces of the semiconductor substrate 10 when the semiconductor device 100 is controlled into an on state. In other words, the active portion is a region in which a current flows inside the semiconductor substrate 10 in a depth direction from the upper surface to the lower surface or from the lower surface to the upper surface of the semiconductor substrate 10. In the present specification, the transistor portion 70 is referred to as an element portion or an element region.

Note that in top view, a region sandwiched between the two element portions is also the active portion 104. In the present example, a region where a gate metal wiring 152 is provided while being sandwiched between the element portions is also included in the active portion 104.

The gate metal wiring 152 is formed of a material containing metal. For example, the gate metal wiring 152 is formed of aluminum, an aluminum-silicon alloy, or an aluminum-silicon-copper alloy. The gate metal wiring 152 is electrically connected to a gate conductive portion of the transistor portion 70, and supplies a gate voltage to the transistor portion 70. The gate metal wiring 152 is provided so as to surround an outer periphery of the active portion 104 in top view. The gate metal wiring 152 is electrically connected to a gate pad 150 provided on the outer peripheral portion 106.

A thickness and a width of the gate metal wiring 152 may not be uniform. The width of the gate metal wiring 152 may be formed to decrease as a distance from the gate pad 150 increases. The width of the gate metal wiring 152 may be formed such that, in a resistance adjustment portion to be described later, the width of the gate metal wiring 152 from the gate pad 150 to the resistance adjustment portion is larger than the width of the gate metal wiring 152 from the resistance adjustment portion to the transistor portion 70. By changing the thickness and the width of the gate metal wiring 152, a gate resistance in a current path from the gate pad 150 to the transistor portion 70 can be finely adjusted.

The outer peripheral portion 106 is a region between the active portion 104 and an end side 102 of the semiconductor substrate 10 in top view. In top view, the outer peripheral portion 106 is provided to enclose the active portion 104. In the outer peripheral portion 106, one or more metal pads for connecting the semiconductor device 100 and an external device by wires or the like may be arranged. Note that the outer peripheral portion 106 may include an edge termination structure portion. The edge termination structure portion reduces electric field strength on the upper surface side of the semiconductor substrate 10. For example, the edge termination structure portion has a structure of a guard ring, a field plate, an RESURF, and a combination thereof.

A front surface side metal layer 110 is provided above the semiconductor substrate 10. The front surface side metal layer 110 may include an emitter electrode 52, an anode pad 130, a cathode pad 140, the gate pad 150, and a current sense pad 190. The front surface side metal layer 110 may be connected to an electrode outside semiconductor device 100 by wire bonding or the like. Note that, a number of at least one front surface side metal layer 110 and a position of the front surface side metal layer 110 are not limited to the present example.

The gate pad 150 is provided above the semiconductor substrate 10. The gate pad 150 is electrically connected to the gate conductive portion of the transistor portion 70 via the gate metal wiring 152. The gate pad 150 is set to a gate potential. The gate pad 150 in the present example has a rectangular shape in top view, but is not limited thereto.

The current sense pad 190 is electrically connected to a current sensing portion 90 to be described later. The current sense pad 190 detects a current flowing through the current sensing portion 90. The current sense pad 190 in the present example has a rectangular shape in top view, but is not limited thereto.

The anode pad 130 is electrically connected to an anode of the temperature sensing portion 180. The anode pad 130 is connected to the anode of the temperature sensing portion 180 by an anode wiring 132. The anode pad 130 in the present example has a rectangular shape in top view, but is not limited thereto.

The cathode pad 140 is electrically connected to a cathode of the temperature sensing portion 180. The cathode pad 140 is connected to the cathode of the temperature sensing portion 180 by a cathode wiring 142. The cathode pad 140 in the present example has a rectangular shape in top view, but is not limited thereto.

The temperature sensing portion 180 is provided above the active portion 104. The temperature sensing portion 180 senses a temperature of the active portion 104. The temperature sensing portion 180 may include a diode formed of monocrystalline or polycrystalline silicon. The temperature sensing portion 180 is used for detecting a temperature of the semiconductor device 100 and protecting the semiconductor chip from overheating. The temperature sensing portion 180 is connected to a constant current source. When the temperature of the semiconductor device 100 changes, a forward voltage of a current flowing through the temperature sensing portion 180 changes. The semiconductor device 100 can detect the temperature based on the change in the forward voltage. The temperature sensing portion 180 has its long side along the Y axis direction and its short side along the X axis direction, but is not limited thereto.

The temperature sensing portion 180 in the present example is provided near a center of the active portion 104 in top view. The temperature sensing portion 180 is provided adjacent to the transistor portion 70. The collector region of the second conductivity type may be provided on a back surface side of the semiconductor substrate 10 provided with the temperature sensing portion 180.

The anode wiring 132 and the cathode wiring 142 are provided above the active portion 104 in top view. In addition, the anode wiring 132 and the cathode wiring 142 are provided to extend from the temperature sensing portion 180 to the outer peripheral portion 106. The anode wiring 132 and the cathode wiring 142 in the present example are provided to extend from the temperature sensing portion 180 in the Y axis direction. The anode wiring 132 and the cathode wiring 142 may be made of a same material as that of the front surface side metal layer 110.

FIG. 1B illustrates an example of an enlarged view of an upper surface of the semiconductor device 100. In the present example, an enlarged view of an end portion of the active portion 104 is illustrated.

The semiconductor device 100 in the present example includes, at the front surface 21 of the semiconductor substrate 10, a gate trench portion 40, a dummy trench portion 30, an emitter region 12, a base region 14, a contact region 15, and a well region 17. In addition, the semiconductor device 100 in the present example includes the emitter electrode 52 and the gate metal wiring 152 provided above the front surface 21 of the semiconductor substrate 10. The gate trench portion 40 is an example of a MOS gate structure provided in the semiconductor device 100.

The emitter electrode 52 is provided above the gate trench portion 40, the dummy trench portion 30, the emitter region 12, the base region 14, the contact region 15, and the well region 17. In addition, the gate metal wiring 152 is provided above a connection portion 25 and the well region 17.

The emitter electrode 52 and the gate metal wiring 152 are formed of a material containing metal. At least a partial region of the emitter electrode 52 may be formed of metal such as aluminum (Al) or of a metal alloy such as an aluminum-silicon alloy (AlSi) or an aluminum-silicon-copper alloy (AlSiCu). At least a partial region of the gate metal wiring 152 may be formed of metal such as aluminum (Al) or a metal alloy such as an aluminum-silicon alloy (AlSi) or an aluminum-silicon-copper alloy (AlSiCu). The emitter electrode 52 and the gate metal wiring 152 may include a barrier metal layer formed of titanium, a titanium compound, or the like below a region formed of aluminum or the like. The barrier metal layer will be described later. The emitter electrode 52 and the gate metal wiring 152 are provided separately from each other.

The emitter electrode 52 and the gate metal wiring 152 are provided above the semiconductor substrate 10 with an interlayer dielectric film 38 interposed therebetween. The interlayer dielectric film 38 is omitted in FIG. 1B. A contact hole 54, a contact hole 55, and a contact hole 56 are provided to penetrate the interlayer dielectric film 38.

A contact hole 53 and the contact hole 55 electrically connect the gate metal wiring 152 and the gate conductive portion in the transistor portion 70 via the connection portion 25. The contact hole 53 connects the gate conductive portion of the gate trench portion 40 and the connection portion 25. An inside of the contact hole 53 may be filled with a same material as that of the connection portion 25. The contact hole 55 connects the connection portion 25 and the gate metal wiring 152. A contact portion formed of tungsten or the like may be formed inside the contact hole 55. The contact portion will be described later.

The contact hole 56 connects the emitter electrode 52 with a dummy conductive portion inside the dummy trench portion 30. A contact portion formed of tungsten or the like may be formed inside the contact hole 56.

The connection portion 25 is connected to the front surface side metal layer 110 such as the emitter electrode 52 or the gate metal wiring 152. In an example, the connection portion 25 is provided between the gate metal wiring 152 and the gate conductive portion. The connection portion 25 in the present example may be provided to extend in the X axis direction and electrically connected to the gate conductive portion. The connection portion 25 may also be provided between the emitter electrode 52 and the dummy conductive portion. In the present example, the connection portion 25 is not provided between the emitter electrode 52 and the dummy conductive portion. The connection portion 25 is formed of a conductive material such as polysilicon doped with impurities. The connection portion 25 in the present example is polysilicon (N+) doped with impurities of the N type. The connection portion 25 may be a polysilicon layer formed in a same step as that of a first polysilicon layer 91 or a second polysilicon layer 92 described later. The connection portion 25 may be provided above the front surface 21 of the semiconductor substrate 10 via a dielectric film such as an oxide film.

The gate trench portions 40 are examples of a plurality of trench portions extending in a predetermined extending direction on a front surface 21 side of the semiconductor substrate 10.

The gate trench portions 40 are arrayed at a predetermined interval along a predetermined array direction (the X axis direction in the present example). The gate trench portion 40 in the present example may have two extending parts 41 which extend along an extending direction (the Y axis direction in the present example) parallel to the front surface 21 of the semiconductor substrate 10 and perpendicular to the array direction, and a connecting part 43 which connects the two extending parts 41.

At least a part of the connecting part 43 is preferably formed in a curved shape. Connecting end portions of the two extending parts 41 of the gate trench portion 40 can reduce electric field strength at the end portions of the extending parts 41. In the connecting part 43 of the gate trench portion 40, the gate metal wiring 152 may be electrically connected to the gate conductive portion via the connection portion 25.

The dummy trench portions 30 are examples of a plurality of trench portions extending in a predetermined extending direction on the front surface 21 side of the semiconductor substrate 10. The dummy trench portion 30 is a trench portion which is electrically connected to the emitter electrode 52. Similarly to the gate trench portions 40, the dummy trench portions 30 are arrayed at a predetermined interval along a predetermined array direction (the X axis direction in the present example). Although the dummy trench portion 30 in the present example has an I shape on the front surface 21 of the semiconductor substrate 10, the dummy trench portion 30 may have a U shape on the front surface 21 of the semiconductor substrate 10, similarly to the gate trench portion 40. That is, the dummy trench portion 30 may include two extending parts extending along the extending direction and a connecting part connecting the two extending parts.

The transistor portion 70 in the present example has a structure in which two gate trench portions 40 and two dummy trench portions 30 are repetitively arrayed. That is, the transistor portion 70 in the present example has the gate trench portions 40 and the dummy trench portions 30 at a ratio of 1:1. For example, the transistor portion 70 has one dummy trench portion 30 between two extending parts 41.

Note that the ratio between the gate trench portions 40 and the dummy trench portions 30 is not limited to that in the present example. The ratio of the gate trench portions 40 may be larger than a ratio of the dummy trench portions 30, or the ratio of the dummy trench portions 30 may be larger than the ratio of the gate trench portions 40. A ratio between the gate trench portions 40 and the dummy trench portions 30 may be 2:3, or may be 2:4. In addition, the transistor portion 70 may not include the dummy trench portions 30 with all trench portions being the gate trench portions 40.

The well region 17 is a region of the second conductivity type which is provided on the front surface 21 side of the semiconductor substrate 10 relative to a drift region 18 to described later. The well region 17 is an example of the well region provided in a peripheral side of the active portion 104. The well region 17 is of the P+type as an example. The well region 17 is formed in a predetermined range from the end portion of the active region on a side where the gate metal wiring 152 is provided. A diffusion depth of the well region 17 may be deeper than depths of the gate trench portion 40 and the dummy trench portion 30. Partial regions of the gate trench portions 40 and the dummy trench portions 30 at the gate metal wiring 152 side are formed in the well region 17. Bottoms of ends in the extending direction of the gate trench portion 40 and the dummy trench portion 30 may be covered with the well region 17.

The contact hole 54 is formed above each region of the emitter region 12 and the contact region 15 in the transistor portion 70. The contact hole 54 is not provided above the well regions 17 provided at both ends in the Y axis direction. In this manner, one or more contact holes 54 are formed in the interlayer dielectric film. The one or more contact holes 54 may be provided to extend in the extending direction.

A mesa portion 71 is a mesa portion provided adjacent to the trench portion in a plane parallel to the front surface 21 of the semiconductor substrate 10. The mesa portion may be a part of the semiconductor substrate 10 sandwiched between two adjacent trench portions, and may be a part from the front surface 21 of the semiconductor substrate 10 to a depth of a lowermost bottom portion of each trench portion. An extending part of each trench portion may be defined as one trench portion. That is, a region sandwiched between two extending parts may be defined as a mesa portion.

The mesa portion 71 is provided adjacent to at least one of the dummy trench portion 30 or the gate trench portion 40 in the transistor portion 70. The mesa portion 71 has the well region 17, the emitter region 12, the base region 14, and the contact region 15 at the front surface 21 of the semiconductor substrate 10. In the mesa portion 71, emitter regions 12 and contact regions 15 are alternately provided in the extending direction.

The base region 14 is a region of the second conductivity type which is provided on the front surface 21 side of the semiconductor substrate 10. The base region 14 is of the P− type as an example. The base regions 14 may be provided at both end portions of the mesa portion 71 in the Y axis direction at the front surface 21 of the semiconductor substrate 10. Note that FIG. 1B illustrates only one end portion of the base region 14 in the Y axis direction.

The emitter region 12 is a region of a first conductivity type which has a doping concentration higher than that of the drift region 18. The emitter region 12 in the present example is of the N+ type as an example. Examples of a dopant of the emitter region 12 include arsenic (As). The emitter region 12 is provided in contact with the gate trench portion 40 at the front surface 21 in the mesa portion 71. The emitter region 12 may be provided to extend in the X axis direction from one to another of two trench portions sandwiching the mesa portion 71. The emitter region 12 is also provided below the contact hole 54.

In addition, the emitter region 12 may be or may not be in contact with the dummy trench portion 30. The emitter region 12 in the present example is in contact with the dummy trench portion 30.

The contact region 15 is a region of the second conductivity type which is provided above the base region 14 and has a doping concentration higher than that of the base region 14. The contact region 15 in the present example is of the P+ type as an example. The contact region 15 in the present example is provided at the front surface 21 in the mesa portion 71. The contact region 15 may be provided in the X axis direction from one to another of the two trench portions sandwiching the mesa portion 71. The contact region 15 may be or may not be in contact with the gate trench portion 40 or the dummy trench portion 30. The contact region 15 in the present example is in contact with the dummy trench portion 30 and the gate trench portion 40. The contact region 15 is also provided below the contact hole 54.

FIG. 1C illustrates an example of a cross section a-a′ in FIG. 1B. The cross section a-a′ is an XZ plane passing through the emitter region 12 in the transistor portion 70. In the cross section a-a′, the semiconductor device 100 in the present example includes the semiconductor substrate 10, the interlayer dielectric film 38, the emitter electrode 52, and a collector electrode 24. The collector electrode 24 is an example of a back surface side metal layer provided in contact with the back surface 23 of the semiconductor substrate 10. The emitter electrode 52 is formed above the semiconductor substrate 10 and the interlayer dielectric film 38.

The drift region 18 is a region of the first conductivity type which is provided in the semiconductor substrate 10. The drift region 18 in the present example is of the N− type as an example. The drift region 18 may be a region which has remained without other doping regions formed in the semiconductor substrate 10. That is, a doping concentration of the drift region 18 may be a doping concentration of the semiconductor substrate 10.

A buffer region 20 is a region of the first conductivity type which is provided on a back surface 23 side of the semiconductor substrate 10 relative to the drift region 18. The buffer region 20 in the present example is of the N type as an example. A doping concentration of the buffer region 20 is higher than the doping concentration of the drift region 18. The buffer region 20 may function as a field stop layer which prevents a depletion layer extending from a lower surface side of the base region 14 from reaching the collector region 22 of the second conductivity type. Note that the buffer region 20 may be omitted.

The collector region 22 is provided below the buffer region 20 in the transistor portion 70. The collector region 22 is of the second conductivity type. The collector region 22 in the present example is of the P+ type as an example.

The collector electrode 24 is formed at the back surface 23 of the semiconductor substrate 10. The collector electrode 24 is formed of a conductive material such as metal. The material of the collector electrode 24 may be a same as or different from the material of the emitter electrode 52.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided above the base region 14. The emitter region 12 is provided between the base region 14 and the front surface 21. The emitter region 12 is provided in contact with the gate trench portion 40. The emitter region 12 may be or may not be in contact with the dummy trench portion 30.

An accumulation region 16 is a region of the first conductivity type which is provided on the front surface 21 side of the semiconductor substrate 10 relative to the drift region 18. The accumulation region 16 in the present example is of the N+ type as an example. Noted that the accumulation region 16 may not be provided.

The accumulation region 16 is provided in contact with the gate trench portion 40. The accumulation region 16 may or may not be in contact with the dummy trench portion 30. A doping concentration of the accumulation region 16 is higher than the doping concentration of the drift region 18. An ion implantation dose amount of the accumulation region 16 may be 1.0E+12 cm⁻² or more and 1.0E+13 cm⁻² or less. Alternatively, the ion implantation dose amount of the accumulation region 16 may be 3.0E+12 cm⁻² or more and 6.0E+12 cm⁻² or less. Providing the accumulation region 16 can increase a carrier injection enhancement effect (IE effect) to reduce an on-voltage of the transistor portion 70.

One or more gate trench portions 40 and one or more dummy trench portions 30 are provided at the front surface 21. Each trench portion is provided from the front surface 21 to the drift region 18. In a region provided with at least any of the emitter region 12, the base region 14, the contact region 15, or the accumulation region 16, each trench portion also penetrates these regions to reach the drift region 18. A configuration in which the trench portion penetrates the doping region is not limited to a configuration which is manufactured in an order of forming the doping region and then forming the trench portion. The configuration in which the trench portion penetrates the doping region includes a configuration in which the trench portions are formed and then the doping region is formed between the trench portions.

The gate trench portion 40 has a gate trench, a gate dielectric film 42, and a gate conductive portion 44 which are formed at the front surface 21. The gate dielectric film 42 is formed to cover an inner wall of the gate trench. The gate dielectric film 42 may be formed by oxidizing or nitriding a semiconductor at the inner wall of the gate trench. The gate conductive portion 44 is formed farther inward than the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered with the interlayer dielectric film 38 on the front surface 21.

The gate conductive portion 44 includes a region opposing the adjacent base region 14 on a mesa portion 71 side with the gate dielectric film 42 interposed therebetween, in the depth direction of the semiconductor substrate 10. When a predetermined voltage is applied to the gate conductive portion 44, a channel is formed by an electron inversion layer in a surface layer of the base region 14 at an interface in contact with the gate trench.

The dummy trench portion 30 may have a same structure as that of the gate trench portion 40. The dummy trench portion 30 has a dummy trench, a dummy dielectric film 32, and a dummy conductive portion 34 which are formed on the front surface 21 side. The dummy dielectric film 32 is formed to cover an inner wall of the dummy trench. The dummy conductive portion 34 is formed inside the dummy trench, and is formed farther inward than the dummy dielectric film 32. The dummy dielectric film 32 insulates the dummy conductive portion 34 from the semiconductor substrate 10. The dummy trench portion 30 may be covered with the interlayer dielectric film 38 on the front surface 21.

The interlayer dielectric film 38 is provided above the semiconductor substrate 10. The interlayer dielectric film 38 in the present example is provided in contact with the front surface 21.

The emitter electrode 52 is provided above the interlayer dielectric film 38. The interlayer dielectric film 38 is provided with one or more contact holes 54 for electrically connecting the emitter electrode 52 to the semiconductor substrate 10. Similarly, the contact hole 53, the contact hole 55, and the contact hole 56 may be provided to penetrate the interlayer dielectric film 38. A film thickness of the interlayer dielectric film 38 may be 0.8 μm or more and 1.2 μm or less.

The interlayer dielectric film 38 may be a silicon oxide film. The interlayer dielectric film 38 may be a boro-phospho silicate glass (BPSG) film, may be a borosilicate glass (BSG) film, or may be a phosphosilicate glass (PSG) film. The interlayer dielectric film 38 may also include a high temperature silicon oxide (HTO: High Temperature Oxide) film.

A back surface side lifetime control region 120 may be provided in the transistor portion 70. However, the back surface side lifetime control region 120 may be omitted. The back surface side lifetime control region 120 is a region where a lifetime killer has intentionally been formed by implanting impurities inside the semiconductor substrate 10, or the like. As an example, the back surface side lifetime control region 120 is formed by implanting helium into the semiconductor substrate 10. The back surface side lifetime control region 120 may also be formed by implanting protons. By providing the back surface side lifetime control region 120, a turn-off time can be reduced, and by suppressing a tail current, losses during switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. Furthermore, the lifetime killer may be a noble gas element such as helium and neon, a metal element such as platinum, or the like. An electron beam or a proton may be used for forming the lattice defect.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. Alternatively, the lifetime killer concentration may be a chemical concentration of the noble gas element such as helium and neon, or may be a chemical concentration of the metal element such as platinum.

The back surface side lifetime control region 120 is provided on the back surface 23 side relative to the center of the semiconductor substrate 10 in the depth direction of the semiconductor substrate 10. The back surface side lifetime control region 120 in the present example is provided in the buffer region 20. The back surface side lifetime control region 120 may be provided on an entire surface of the semiconductor substrate 10 in an XY plane by being formed without using a mask. The back surface side lifetime control region 120 may be provided on a part of the semiconductor substrate 10 in the XY plane by being formed using a mask. An impurity dose amount for forming the back surface side lifetime control region 120 may be 0.5E+10 cm⁻² or more and 1.0E+14 cm⁻² or less, or may be 5.0E+10 cm⁻² or more and 1.0E+13 cm⁻² or less.

The back surface side lifetime control region 120 may be formed by an implantation from the back surface 23 side. Accordingly, it becomes easy to avoid an effect on the front surface 21 side of the semiconductor device 100. For example, the back surface side lifetime control region 120 is formed by radiating helium or protons from the back surface 23 side. Herein, which of the front surface 21 side and the back surface 23 side the implantation is performed from for forming the back surface side lifetime control region 120 can be determined by acquiring a state of the front surface 21 side by an SR method or a measurement of a leakage current.

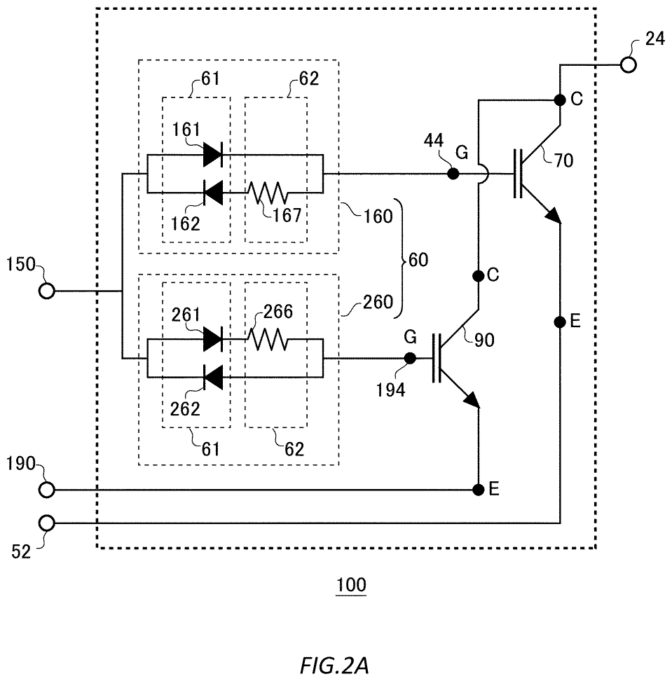

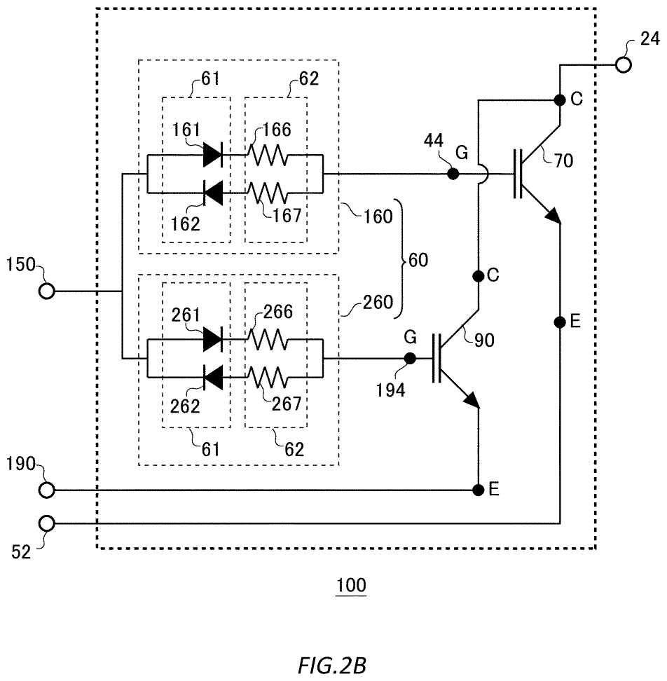

FIG. 2A illustrates an example of a circuit configuration of the semiconductor device 100. The semiconductor device 100 in the present example includes a resistance adjustment portion 60. In the semiconductor device 100, the transistor portion 70 and the current sensing portion 90 are connected in parallel to each other.

The resistance adjustment portion 60 is electrically connected to the gate pad 150, and adjusts gate resistances of the transistor portion 70 and the current sensing portion 90. The resistance adjustment portion 60 includes a main adjustment portion 160 and a sense adjustment portion 260.

The main adjustment portion 160 is electrically connected to the gate conductive portion 44 of the transistor portion 70. The sense adjustment portion 260 is electrically connected to a gate conductive portion 194 of the current sensing portion 90. The gate conductive portion 194 will be described later. Each of the main adjustment portion 160 and the sense adjustment portion 260 includes a diode element portion 61 and a resistance portion 62.

The diode element portion 61 includes a plurality of diodes provided in anti-parallel. Since the diode element portion 61 includes the plurality of diodes provided in anti-parallel, a gate wiring for turning on gates of the transistor portion 70 and the current sensing portion 90 and a gate wiring for turning off the gates can be set to different paths. Accordingly, different resistance values can be set between on and off of the gates.

The resistance portion 62 is connected to the diode element portion 61. The resistance portion 62 has a resistance value such that the transistor portion 70 is turned on before the current sensing portion 90, and the transistor portion 70 is turned off later than the current sensing portion 90. The resistance value of the resistance portion 62 may be set in consideration of a built-in gate resistance of the transistor portion 70 and a built-in gate resistance of the current sensing portion 90. The built-in gate resistance may be a parasitic gate resistance generated by a gate wiring resistor or the like.

The main adjustment portion 160 includes a main on-side diode 161 and a main off-side diode 162 as the diode element portion 61. The main on-side diode 161 and the main off-side diode 162 are connected in anti-parallel between the gate pad 150 and the gate conductive portion 44. The main adjustment portion 160 includes a main off-side resistor 167 as the resistance portion 62.

The main on-side diode 161 has an anode electrically connected to the gate pad 150 and a cathode electrically connected to the gate conductive portion 44 of the transistor portion 70. The main off-side diode 162 has an anode electrically connected to the gate conductive portion 44 of the transistor portion 70 and a cathode electrically connected to the gate pad 150.

The main off-side resistor 167 is connected in series with the main off-side diode 162 between the gate pad 150 and the gate conductive portion 44. The main off-side resistor 167 in the present example is electrically connected between the anode of the main off-side diode 162 and the gate conductive portion 44 of the transistor portion 70. The main off-side resistor 167 may be connected between the cathode of the main off-side diode 162 and the gate pad 150. The main off-side resistor 167 may be set such that an off operation of the transistor portion 70 is later than an off operation of the current sensing portion 90.

The main adjustment portion 160 in the present example adjusts only the gate resistance on the off side and does not adjust the gate resistance on the on side. However, the main adjustment portion 160 may adjust the gate resistances on both the on side and the off side, or may adjust only the gate resistance on the on side.

The sense adjustment portion 260 includes a sense on-side diode 261 and a sense off-side diode 262 as the diode element portion 61. The sense on-side diode 261 and the sense off-side diode 262 are connected in anti-parallel between the gate pad 150 and the gate conductive portion 194. The sense adjustment portion 260 includes a sense on-side resistor 266 as the resistance portion 62.

The sense on-side diode 261 has an anode electrically connected to the gate pad 150 and a cathode electrically connected to the gate conductive portion 194 of the current sensing portion 90. The sense off-side diode 262 has an anode electrically connected to the gate conductive portion 194 of the current sensing portion 90 and a cathode electrically connected to the gate pad 150.

The sense on-side resistor 266 is connected in series with the sense on-side diode 261 between the gate pad 150 and the gate conductive portion 194. The sense on-side resistor 266 in the present example is electrically connected between the cathode of the sense on-side diode 261 and the gate conductive portion 194 of the current sensing portion 90. The sense on-side resistor 266 may be connected between the anode of the sense on-side diode 261 and the gate pad 150. The sense on-side resistor 266 may be set such that an on operation of the current sensing portion 90 is later than an on operation of the transistor portion 70.

The sense adjustment portion 260 in the present example adjusts only the gate resistance on the on side and does not adjust the gate resistance on the off side. However, the sense adjustment portion 260 may adjust the gate resistance on both the on side and the off side, or may adjust only the gate resistance on the off side.

Since the semiconductor device 100 in the present example includes the resistance adjustment portion 60, switching speeds of the transistor portion 70 and the current sensing portion 90 can be adjusted. Accordingly, the semiconductor device 100 can suppress gate oscillation in the chip.

FIG. 2B illustrates a modification of the circuit configuration of the semiconductor device 100. The semiconductor device 100 in the present example is different from the example of FIG. 2A in including a main on-side resistor 166 and a sense off-side resistor 267. In the present example, differences from the example of FIG. 2A will be particularly described.

The main on-side resistor 166 is electrically connected between the cathode of the main on-side diode 161 and the gate conductive portion 44 of the transistor portion 70. That is, the main on-side resistor 166 may be connected in series with the main on-side diode 161 and connected in parallel with the main off-side resistor 167 between the gate pad 150 and the gate conductive portion 44. The main on-side resistor 166 may be electrically connected between the anode of the main on-side diode 161 and the gate pad 150.

The sense off-side resistor 267 is electrically connected between the anode of the sense off-side diode 262 and the gate conductive portion 194 of the current sensing portion 90. That is, the sense off-side resistor 267 may be connected in series with the sense off-side diode 262 and connected in parallel with the sense on-side resistor 266 between the gate pad 150 and the gate conductive portion 194. The sense off-side resistor 267 may be connected between the cathode of the sense off-side diode 262 and the gate pad 150.

In the semiconductor device 100 in the present example, the switching speed during the on operation of the transistor portion 70 and the switching speed during the off operation of the current sensing portion 90 can be further adjusted. That is, the semiconductor device 100 in the present example can adjust the switching speed during the on/off operation of the transistor portion 70 and adjust the switching speed during the on/off operation of the current sensing portion 90.

The resistance adjustment portion 60 has a resistance value such that the transistor portion 70 is turned on before the current sensing portion 90, and the transistor portion 70 is turned off later than the current sensing portion 90. A resistance value of the main on-side resistor 166 may be smaller than a resistance value of the sense on-side resistor 266. The resistance value of the main on-side resistor 166 may be 5 times or more and 100 times or less the resistance value of the sense on-side resistor 266. A resistance value of the main off-side resistor 167 may be larger than a resistance value of the sense off-side resistor 267. The resistance value of the main off-side resistor 167 may be 1 time or more and 10 times or less the resistance value of the sense off-side resistor 267.

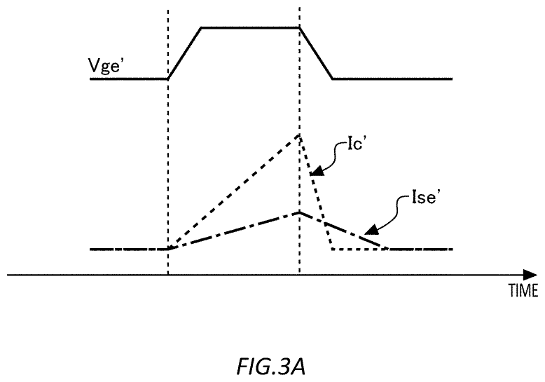

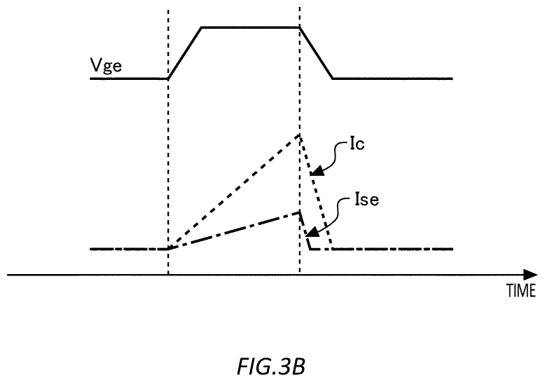

FIG. 3A illustrates waveforms of a collector current Ic′ and a sense current Ise′ flowing through a semiconductor device of a comparative example. In the comparative example, when a gate voltage Vge′ is turned off, the sense current Ise′ is turned off later than the collector current Ic'. In this manner, when turn-off of a sensing portion is later than turn-off of a main transistor portion, a current flows into the sensing portion, and the current sensing portion may be broken or an oscillation phenomenon may occur. Similarly, when turn-on of the sensing portion is earlier than turn-on of the main transistor portion, a current flows into the sensing portion, and the current sensing portion may be broken or an oscillation phenomenon may occur.

FIG. 3B illustrates waveforms of a collector current Ic and a sense current Ise flowing through the semiconductor device 100. In the present example, when the gate voltage Vge is turned off, the sense current Ise of the current sensing portion 90 is turned off before the collector current Ic of the transistor portion 70. In this manner, the semiconductor device 100 can avoid breakdown of the current sensing portion 90 by adjusting the switching speed such that turn-off of the current sensing portion 90 is earlier than turn-off of the transistor portion 70. Similarly, the semiconductor device 100 may avoid breakdown of the current sensing portion 90 by adjusting the switching speed such that turn-on of the current sensing portion 90 occurs at a same time as or later than turn-on of the transistor portion 70.

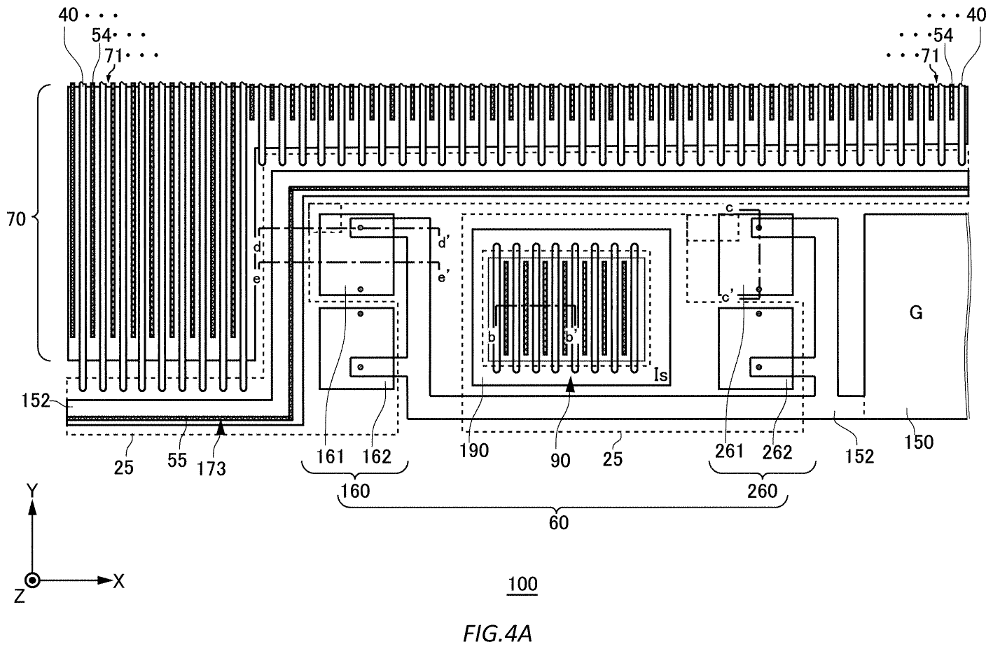

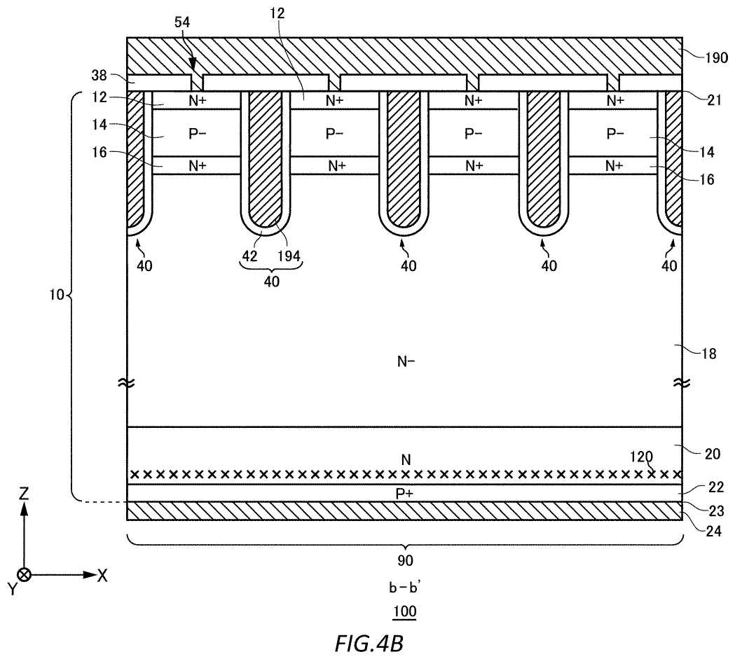

FIG. 4A illustrates an example of an enlarged view of the upper surface around the current sense pad 190 and the gate pad 150. In the transistor portion 70 in the present example, all trench portions are the gate trench portions 40, but the transistor portion 70 may include the dummy trench portion 30. The structure of the transistor portion 70 may be the same as that of the semiconductor device 100 in FIG. 1B. The semiconductor device 100 includes the current sensing portion 90 and the resistance adjustment portion 60.

The current sensing portion 90 detects a current flowing through the transistor portion 70. A trench structure of the current sensing portion 90 is provided below the current sense pad 190. The current sensing portion 90 has a structure corresponding to the transistor portion 70, and simulates the operation of the transistor portion 70. Since a current proportional to the current flowing through the transistor portion 70 flows through the current sensing portion 90, the current flowing through the transistor portion 70 can be monitored by using the current sensing portion 90. Accordingly, it is possible to protect the transistor portion 70 from overcurrent.

The gate pad 150 may be provided in common between the transistor portion 70 and the current sensing portion 90. That is, a common gate control signal may be input to the transistor portion 70 and the current sensing portion 90. The gate pad 150 may be provided in common between the main adjustment portion 160 and the sense adjustment portion 260. The gate pad 150 is connected to the main adjustment portion 160 and the sense adjustment portion 260 by the gate metal wiring 152.

The main adjustment portion 160 may be provided adjacent to the transistor portion 70. The main adjustment portion 160 in the present example is provided further away from the gate pad 150 than the current sense pad 190, but may be provided closer to the gate pad 150 than the current sense pad 190. The main adjustment portion 160 may be connected to the transistor portion 70 by using at least one of the connection portion 25 or the gate metal wiring 152. The main adjustment portion 160 in the present example is connected to the transistor portion 70 by the connection portion 25.

The main on-side diode 161 and the main off-side diode 162 may be arranged adjacent to each other. Being arranged adjacent to each other may mean that the gate metal wiring 152 is not present between the main on-side diode 161 and the main off-side diode 162. The main on-side diode 161 and the main off-side diode 162 in the present example are arranged side by side in the extending direction of the trench, but are not limited thereto.

The sense adjustment portion 260 may be provided adjacent to the current sense pad 190. That is, the gate metal wiring 152 may not be provided between the sense adjustment portion 260 and the current sense pad 190. The sense adjustment portion 260 in the present example is provided between the current sense pad 190 and the gate pad 150, but is not limited thereto. The sense adjustment portion 260 may be connected to the current sensing portion 90 by using at least one of the connection portion 25 or the gate metal wiring 152. The sense adjustment portion 260 in the present example is connected to the current sensing portion 90 by the connection portion 25.

The sense on-side diode 261 and the sense off-side diode 262 may be arranged adjacent to each other. That is, the gate metal wiring 152 may not be provided between the sense on-side diode 261 and the sense off-side diode 262. The sense on-side diode 261 and the sense off-side diode 262 in the present example are arranged side by side in the extending direction of the trench, but are not limited thereto.

The gate metal wiring 152 may connect the gate pad 150 and the resistance adjustment portion 60. The gate metal wiring 152 in the present example connects each of the main on-side diode 161, the main off-side diode 162, the sense on-side diode 261, and the sense off-side diode 262 to the gate pad 150. The gate metal wiring 152 may be connected to the main adjustment portion 160 by using a third contact portion 173 provided in the contact hole 55.

The resistance adjustment portion 60 may have a stacked structure in which the diode element portion 61 and the resistance portion 62 are stacked. By stacking the diode element portion 61 and the resistance portion 62 to increase an area of the resistance adjustment portion 60, an ESD breakdown tolerance can be improved. The main on-side diode 161 may be provided to be stacked with the main on-side resistor 166. The main off-side diode 162 may be provided to be stacked with the main off-side resistor 167. The sense on-side diode 261 may be provided to be stacked with the sense on-side resistor 266. The sense off-side diode 262 may be provided to be stacked with the sense off-side resistor 267.

Here, the switching speeds of the transistor portion 70 and the current sensing portion 90 may change according to areas and the like thereof. The area of the current sensing portion 90 may be restricted depending on a chip size, an arrangement position of the pad, and the like. In the semiconductor device 100 in the present example, the switching speed can be adjusted according to a capacitance ratio based on the areas and the like of the transistor portion 70 and the current sensing portion 90, and thus it is possible to suppress the gate oscillation in the chip regardless of a chip layout.

FIG. 4B illustrates an example of a cross section b-b′ in FIG. 4A. The cross section b-b′ is an XZ plane passing through the emitter region 12 in the current sensing portion 90. The semiconductor device 100 in the present example includes the semiconductor substrate 10, the interlayer dielectric film 38, the current sense pad 190, and the collector electrode 24 in the cross section b-b′. The current sense pad 190 is formed above the semiconductor substrate 10 and the interlayer dielectric film 38. The current sensing portion 90 may include the contact region 15 similarly to the transistor portion 70.

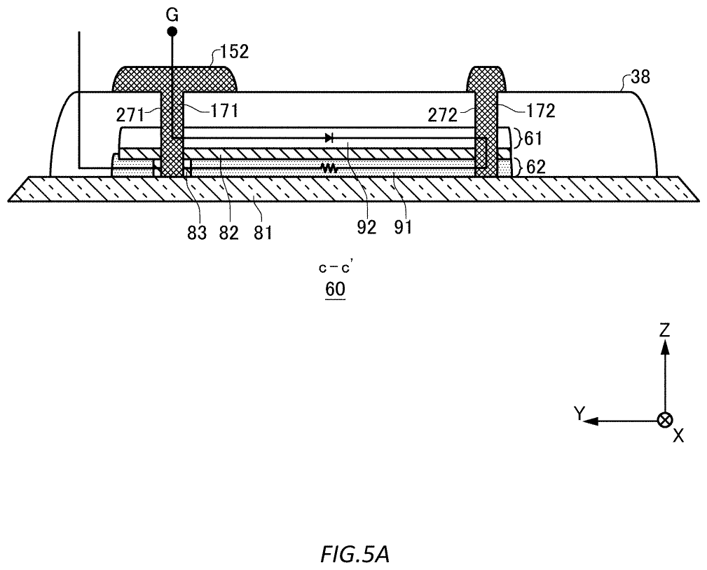

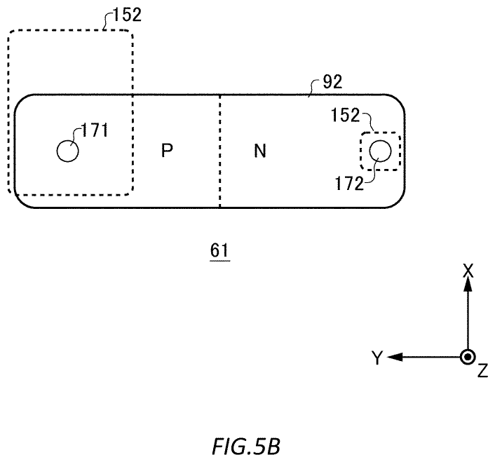

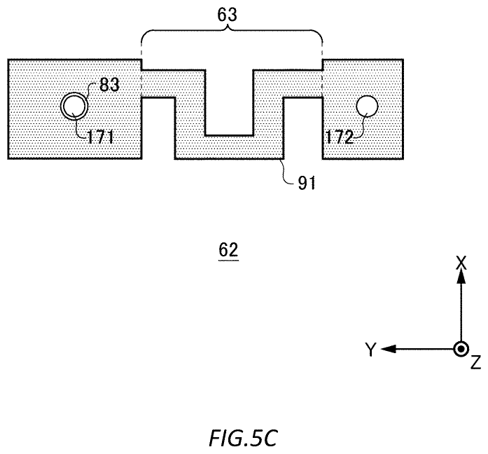

FIG. 5A illustrates an example of a cross section c-c′ in FIG. 4A. The resistance adjustment portion 60 in the present example has a stacked structure in which the diode element portion 61 and the resistance portion 62 are stacked. The cross section c-c′ is a YZ plane passing through a first contact portion 171 and a second contact portion 172 in the resistance adjustment portion 60. The cross section c-c′ shows a region of the sense on-side diode 261 in the resistance adjustment portion 60 in FIG. 4A, but the same may apply to cross sections of the main on-side diode 161, the main off-side diode 162, and the sense off-side diode 262.

The diode element portion 61 is provided above the resistance portion 62. The diode element portion 61 in the present example is provided above the resistance portion 62 with a second insulating portion 82 interposed therebetween. The diode element portion 61 may be provided below the resistance portion 62. The diode element portion 61 may be any one of the main on-side diode 161, the main off-side diode 162, the sense on-side diode 261, or the sense off-side diode 262. The resistance portion 62 may be any of the main on-side resistor 166, the main off-side resistor 167, the sense on-side resistor 266, or the sense off-side resistor 267.

The first contact portion 171 is provided to connect the front surface side metal layer 110 and the diode element portion 61. The first contact portion 171 in the present example connects the gate metal wiring 152 and the diode element portion 61. The first contact portion 171 is provided to extend from an upper end of the interlayer dielectric film 38 to an upper end of a first insulating portion 81 through the diode element portion 61, the second insulating portion 82, and the resistance portion 62. A material of the first contact portion 171 may be the same as that of the front surface side metal layer 110. The first contact portion 171 may include a plug member such as tungsten and may include a barrier metal. The first contact portion 171 is provided inside a first opening 271.

The second contact portion 172 is provided to connect the front surface side metal layer 110 and the resistance portion 62. The second contact portion 172 in the present example connects the diode element portion 61 and the resistance portion 62. The second contact portion 172 is provided to extend from the upper end of the interlayer dielectric film 38 to the upper end of the first insulating portion 81 through the diode element portion 61, the second insulating portion 82, and the resistance portion 62. A material of the second contact portion 172 may be the same as that of the front surface side metal layer 110. The second contact portion 172 may include a plug member such as tungsten and may include a barrier metal. The second contact portion 172 is provided inside a second opening 272.

The first opening 271 and the second opening 272 may be formed by a common etching process. That is, depths of the first opening 271 and the second opening 272 may be the same. The first opening 271 and the second opening 272 may be formed by a same etching process as that of the contact hole of the transistor portion 70. For example, the first opening 271 and the second opening 272 are formed by a same etching process as the contact hole 54, the contact hole 55, and the contact hole 56.

The first insulating portion 81 is provided above the semiconductor substrate 10. The first insulating portion 81 may be an oxide film such as an HTO film. The resistance portion 62 in the present example is provided on the first insulating portion 81.

The second insulating portion 82 is provided above the first insulating portion 81. The second insulating portion 82 may be an oxide film such as an HTO film. The second insulating portion 82 may be used to separate the diode element portion 61 and the resistance portion 62 which are stacked.

The interlayer dielectric film 38 may be provided above the first insulating portion 81 and the second insulating portion 82. The interlayer dielectric film 38 may be formed by a process common with that of the interlayer dielectric film 38 of the transistor portion 70 and the current sensing portion 90, or may be formed by a process different therefrom. The thickness of the interlayer dielectric film 38 may be larger than a thickness of the first insulating portion 81 and may be larger than a thickness of the second insulating portion 82. The gate metal wiring 152 may be provided on the interlayer dielectric film 38.

A third insulating portion 83 is provided around the first contact portion 171 and electrically separates the first contact portion 171 from the resistance portion 62. The third insulating portion 83 may be formed by a same process as that of the second insulating portion 82. A material of the third insulating portion 83 may be the same as a material of the second insulating portion 82.

The diode element portion 61 and the resistance portion 62 may be formed of polysilicon. The diode element portion 61 may be formed in the second polysilicon layer 92, and the resistance portion 62 may be formed in the first polysilicon layer 91.

The first polysilicon layer 91 is provided on the first insulating portion 81. The first polysilicon layer 91 may be a polysilicon layer formed by a process common with that of at least one of the gate conductive portion 44 or the gate conductive portion 194. The first polysilicon layer 91 may be polysilicon formed by a process common with that of the connection portion 25. The polysilicon formed by the common process may be polysilicon formed simultaneously by using a same mask. A thickness of the first polysilicon layer 91 may be 0.5 μm or more and 1 μm or less.

The second polysilicon layer 92 is provided on the second insulating portion 82. The second polysilicon layer 92 may be polysilicon formed by a process common with that of a temperature sense diode of the temperature sensing portion 180. A thickness of the second polysilicon layer 92 may be smaller than the thickness of the first polysilicon layer 91. That is, a thickness of the resistance portion 62 may be smaller than a thickness of the diode element portion 61. The thickness of the second polysilicon layer 92 may be 0.3 μm or more and 0.7 μm or less.

FIG. 5B illustrates an example of a top view of the diode element portion 61. The diode element portion 61 includes a P type region and an N type region provided in the second polysilicon layer 92. The diode element portion 61 in the present example has one PN junction, but may have a plurality of PN junctions connected in series. The PN junction of the diode element portion 61 may be formed by ion implantation. Each of the P type region and the N type region may be formed by ion implantation. The P type region and the N type region may be formed by depositing a polysilicon layer of one conductivity type of the P type or the N type and then performing ion implantation of another conductivity type.

A structure of the diode element portion 61 in the present example may be a structure of at least one of the main on-side diode 161, the main off-side diode 162, the sense on-side diode 261, or the sense off-side diode 262. Structures of the main on-side diode 161, the main off-side diode 162, the sense on-side diode 261, and the sense off-side diode 262 may be common or may be different from each other.

FIG. 5C illustrates an example of a top view of the resistance portion 62. The resistance portion 62 includes the first polysilicon layer 91 connected to the second contact portion 172. The resistance portion 62 in the present example has a resistance region 63 for adjusting the gate resistance. In the resistance portion 62, the resistance may be adjusted by a shape of the first polysilicon layer 91, or the resistance may be adjusted by a doping concentration of the first polysilicon layer 91. The resistance region 63 in the present example includes a region in which the first polysilicon layer 91 meanders on the XY plane. The first polysilicon layer 91 may be the P type or the N type.

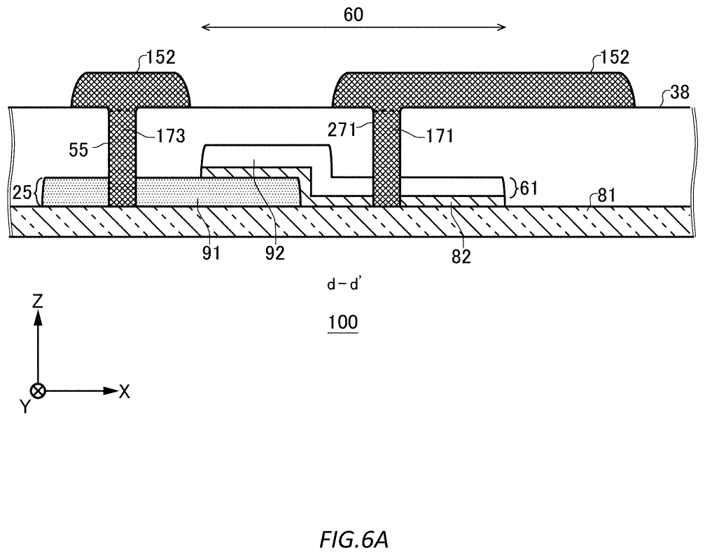

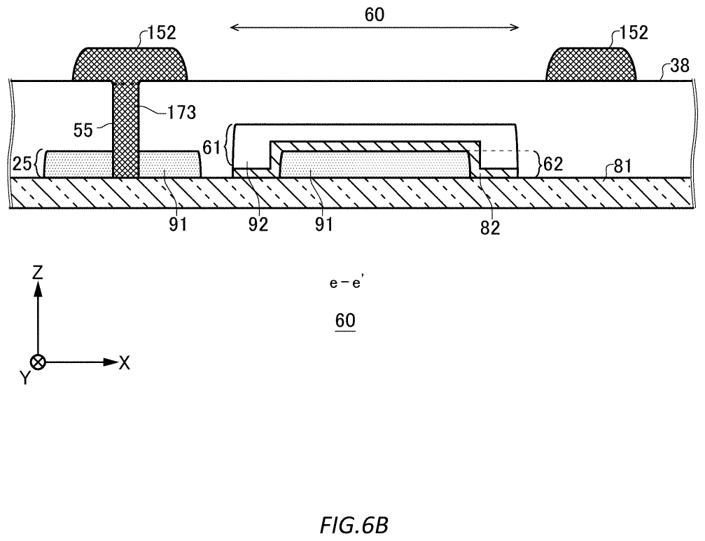

FIG. 6A illustrates an example of a cross section d-d′ in FIG. 4A. The cross section d-d′ is an XZ plane passing through the connection portion 25 for connecting the resistance adjustment portion 60 and the transistor portion 70. The cross section d-d′ passes through the first contact portion 171 and the third contact portion 173.

The diode element portion 61 may or may not overlap the connection portion 25 in top view. The diode element portion 61 in the present example overlaps the connection portion 25 and is also provided above the connection portion 25. The diode element portion 61 and the connection portion 25 may be separated by the second insulating portion 82. The connection portion 25 may be connected to the gate metal wiring 152 via the third contact portion 173.

The third contact portion 173 is used to connect the gate metal wiring 152 and the connection portion 25. The third contact portion 173 is provided to extend from the upper end of the interlayer dielectric film 38 to the upper end of the first insulating portion 81 through the connection portion 25. The third contact portion 173 may terminate at an upper surface of the connection portion 25 without penetrating the connection portion 25. A material of the third contact portion 173 may be the same as that of the front surface side metal layer 110. The third contact portion 173 may include a plug member such as tungsten and may include a barrier metal. The third contact portion 173 is provided inside the contact hole 55.

FIG. 6B illustrates an example of a cross section e-e′ in FIG. 4A. The cross section e-e′ is an XZ plane passing through the resistance portion 62 and the connection portion 25. The cross section e-e′ crosses the resistance adjustment portion 60 in the X axis direction and passes through the third contact portion 173.

The diode element portion 61 may be provided to cover the resistance portion 62. A width in the X axis direction of the diode element portion 61 in the present example is larger than a width in the X axis direction of the resistance portion 62. A width in the Y axis direction of the diode element portion 61 may be larger or smaller than a width in the Y axis direction of the resistance portion 62.

The first polysilicon layer 91 functioning as the connection portion 25 may be provided below the gate metal wiring 152. The first polysilicon layer 91 functioning as the connection portion 25 is separated from the second polysilicon layer 92 functioning as the diode element portion 61 by the interlayer dielectric film 38.

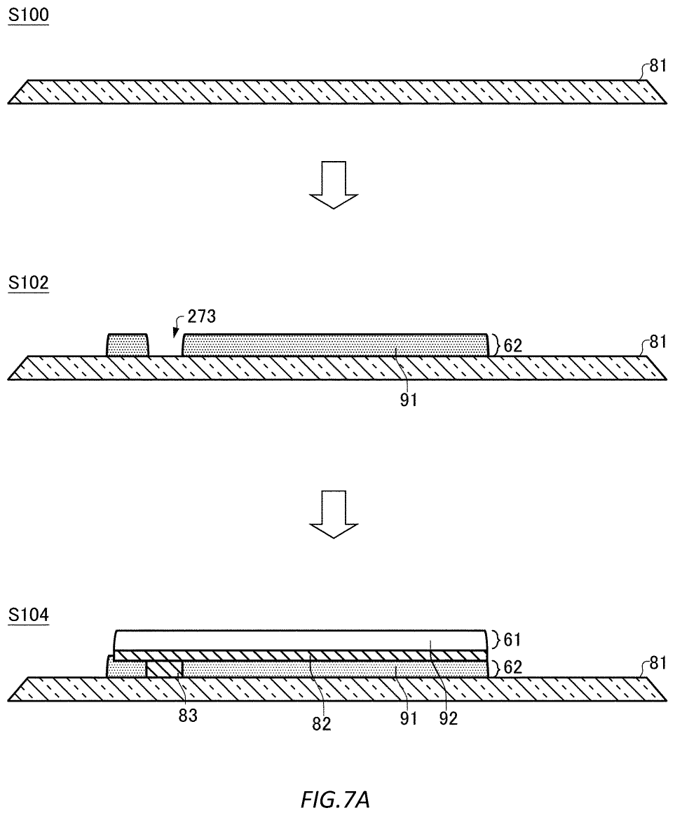

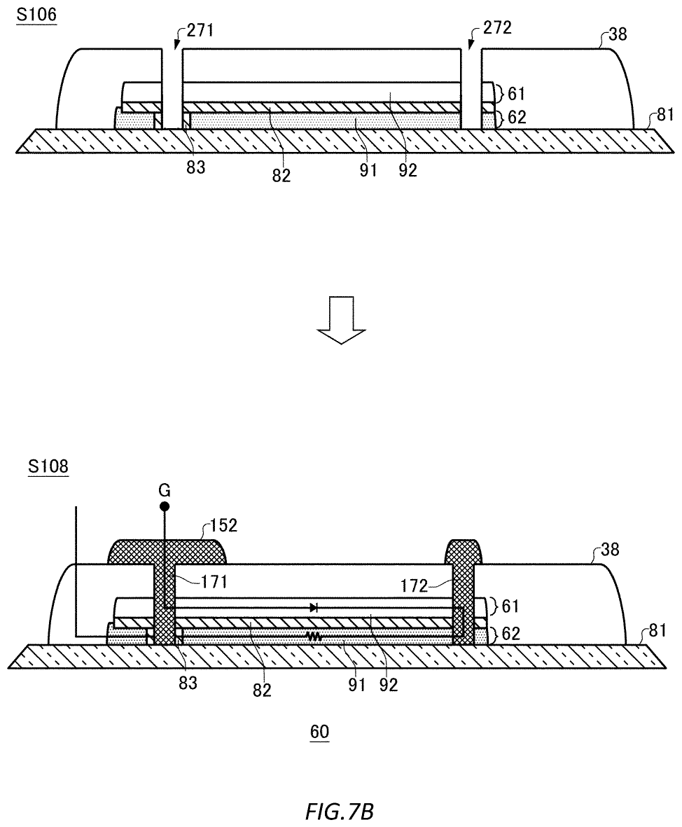

FIG. 7A illustrates an example of a method for manufacturing the semiconductor device 100 including the resistance adjustment portion 60. In step S100, the first insulating portion 81 is formed above the semiconductor substrate 10.

In step S102, the first polysilicon layer 91 for forming the resistance portion 62 is formed on the first insulating portion 81. The first polysilicon layer 91 may be patterned according to a shape of the resistance portion 62. The first polysilicon layer 91 may be formed simultaneously with the gate conductive portion 44 and the gate conductive portion 194. A third opening 273 may be formed in the first polysilicon layer 91 before a step of forming the second insulating portion 82. The third opening 273 may be an opening for forming the first contact portion 171 and the third insulating portion 83. However, the formation of the third opening 273 may be omitted.

In step S104, the second insulating portion 82 is formed on the first polysilicon layer 91. When the third opening 273 is formed, the third insulating portion 83 may be formed inside the third opening 273. The third insulating portion 83 may be formed by the same process as that of the second insulating portion 82. The material of the third insulating portion 83 may be the same as the material of the second insulating portion 82. When the second insulating portion 82 is formed, a contact hole 57 to be described later may be formed by patterning, etching, or the like. The second polysilicon layer 92 for forming the diode element portion 61 is formed on the second insulating portion 82. The second polysilicon layer 92 may be formed by the process common with that of the temperature sense diode of the temperature sensing portion 180. A PN structure of the diode element portion 61 may be formed by a process common with that of a PN structure of the temperature sensing portion 180. The second polysilicon layer 92 may be formed up to an inside of the contact hole 57.

FIG. 7B illustrates an example of the method for manufacturing the semiconductor device 100 including the resistance adjustment portion 60. This drawing illustrates a step subsequent to the method for manufacturing the semiconductor device 100 of FIG. 7A.

In step S106, the interlayer dielectric film 38 is formed above the diode element portion 61 and the resistance portion 62. After the interlayer dielectric film 38 is formed, the first opening 271 for forming the first contact portion 171 may be formed to penetrate the interlayer dielectric film 38, the second polysilicon layer 92, and the second insulating portion 82. After the interlayer dielectric film 38 is formed, the second opening 272 for forming the second contact portion 172 may be formed to penetrate the interlayer dielectric film 38, the second polysilicon layer 92, the second insulating portion 82, and the first polysilicon layer 91. In step S104, when the contact hole 57 is formed, the second opening 272 may not be formed.

The first opening 271 and the second opening 272 may be formed by a same etching process. The first opening 271 and the second opening 272 may reach an upper surface of the first insulating portion 81. The first opening 271 and the second opening 272 may extend inside the first insulating portion 81 or may not reach the upper surface of the first insulating portion 81.

The step of forming the first opening 271 may include a step of forming the first opening 271 to penetrate the third insulating portion 83. In the step of forming the first opening 271, in order to separate the first contact portion 171, which fills the first opening 271, from the resistance portion 62, the first opening 271 is formed such that the third insulating portion 83 is provided between the first opening 271 and the first polysilicon layer 91.

In step S108, the first contact portion 171 is formed in the first opening 271, and the second contact portion 172 is formed in the second opening 272. The first contact portion 171 and the second contact portion 172 may be formed by a same contact forming process. The step of forming the first contact portion 171 may include a step of forming the first contact portion 171 inside the third insulating portion 83. In step S106, when the second opening 272 is not formed, the second contact portion 172 may not be formed.

In the method for manufacturing the semiconductor device 100 in the present example, the process can be simplified by making at least a part of the step for forming the resistance adjustment portion 60 common with the step for forming the transistor portion 70, the current sensing portion 90, or the temperature sensing portion 180. By making all the steps of the resistance adjustment portion 60 common, a new step for forming the resistance adjustment portion 60 can be made unnecessary.

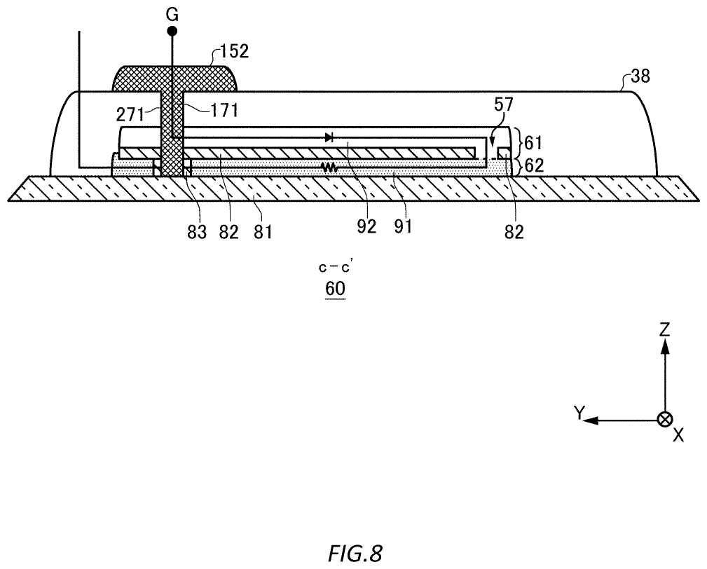

FIG. 8 illustrates a modification of the cross section c-c′ in FIG. 4A. Differences from FIG. 5A will be described with reference to FIG. 8.

In the example of FIG. 8, the diode element portion 61 and the resistance portion 62 are in direct contact with each other via the contact hole 57 provided in the second insulating portion 82. That is, in the example of FIG. 8, the second contact portion 172 and the second opening 272 are not provided. By bringing the diode element portion 61 and the resistance portion 62 into direct contact with each other, a size of the contact hole 57 can be adjusted, thereby adjusting characteristics and adjusting the resistance value of the resistance portion 62.

Inside the contact hole 57, a height of an interface between the diode element portion 61 and the resistance portion 62 may be the same as a height of a lower surface of the second insulating portion 82. As an example, the contact hole 57 is formed by forming the second insulating portion 82 on the first polysilicon layer 91 and then selectively removing the second insulating portion 82 by etching or the like. Note that by performing over-etching when the second insulating portion 82 is removed, the height of the interface between the diode element portion 61 and the resistance portion 62 may be located below the height of the lower surface of the second insulating portion 82.

Inside the contact hole 57, the height of the interface between the diode element portion 61 and the resistance portion 62 may be located above the height of the lower surface of the second insulating portion 82. That is, the first polysilicon layer 91 may be provided to extend to the inside of the contact hole 57 in the depth direction of the semiconductor substrate 10. As an example, the contact hole 57 is formed by selectively forming a mask on the first polysilicon layer 91, etching the first polysilicon layer 91, then forming the second insulating portion 82 on the first polysilicon layer 91, and removing the mask.

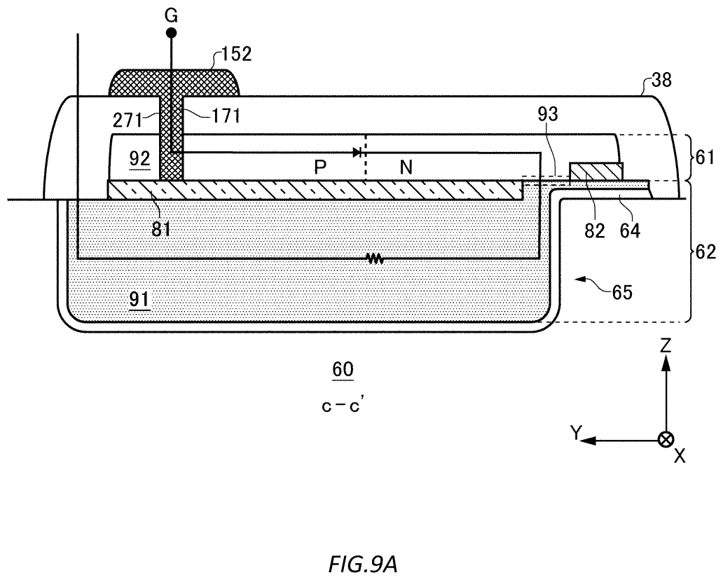

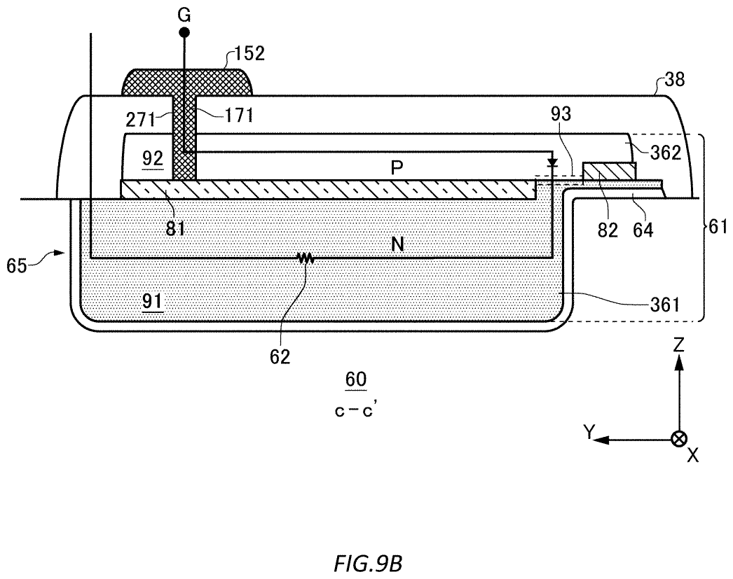

FIG. 9A illustrates a modification of the cross section c-c′ in FIG. 4A. The resistance adjustment portion 60 in the present example is different from the example illustrated in FIG. 5A or the like in that the resistance adjustment portion 60 includes a resistance adjustment trench portion 65, which is provided to extend in a predetermined direction, in the semiconductor substrate 10. Difference from the example of the cross section c-c′ illustrated in FIG. 5A will be described with reference to FIG. 9A.

The first polysilicon layer 91 is provided inside the resistance adjustment trench portion 65. That is, in the example illustrated in FIG. 9A, the first polysilicon layer 91 is not provided on the first insulating portion 81 formed above the front surface 21 of the semiconductor substrate 10, but is provided inside the resistance adjustment trench portion 65 which is provided to extend in the depth direction from the front surface 21 of the semiconductor substrate 10. The first polysilicon layer 91 may function as the resistance portion 62.

The resistance adjustment trench portion 65 in the present example includes a resistance adjustment dielectric film 64 and a first polysilicon layer 91. The resistance adjustment dielectric film 64 may be formed by oxidizing or nitriding a semiconductor on an inner wall of a resistance adjustment trench. The first polysilicon layer 91 is formed farther inward than the resistance adjustment dielectric film 64 inside the resistance adjustment trench portion 65. The resistance adjustment dielectric film 64 insulates the first polysilicon layer 91 from the semiconductor substrate 10.

The second polysilicon layer 92 is provided on the first insulating portion 81, the second insulating portion 82, and the first polysilicon layer 91. The first insulating portion 81 and the second insulating portion 82 may be formed in a same step or may be formed in different steps. The second polysilicon layer 92 may function as the diode element portion 61. An interface 93 is formed between the first polysilicon layer 91 and the second polysilicon layer 92.

The second polysilicon layer 92 is provided in direct contact with the first polysilicon layer 91. That is, in the example of FIG. 9A, the second contact portion 172 and the second opening 272 are not provided. Accordingly, the diode element portion 61 and the resistance portion 62 can be brought into direct contact with each other, and by adjusting a size of the contact interface 93 at the contact, a resistance value of the resistance adjustment portion 60 can be adjusted. Note that in the example of FIG. 9A, the second contact portion 172 and the second opening 272 may be provided.

FIG. 9B illustrates a modification of the cross section c-c′ in FIG. 4A. The example of FIG. 9B is different from the example illustrated in FIG. 9A in that the first polysilicon layer 91 provided in the resistance adjustment trench portion 65 functions as a part of the resistance portion 62 and the diode element portion 61.

The diode element portion 61 includes a cathode region 361 and an anode region 362. The cathode region 361 is a region of the first conductivity type. The cathode region 361 in the present example is the N type. The anode region 362 is a region of the second conductivity type. The anode region 362 in the present example is the P type. In the diode element portion 61, a current flows in a direction from the anode region 362 toward the cathode region 361.

At least one of the cathode region 361 or the anode region 362 may be provided in the resistance adjustment trench portion 65. In the present example, the cathode region 361 is provided in the resistance adjustment trench portion 65 which is provided to extend in a predetermined direction in the semiconductor substrate 10. The anode region 362 may be provided in the resistance adjustment trench portion 65.

In this manner, the first polysilicon layer 91 may function not only as the resistance portion 62 but also as one of the cathode region 361 or the anode region 362 of the diode element portion 61. Accordingly, by changing the size of the interface 93, the characteristics of the diode element portion 61 can be adjusted, or the resistance adjustment portion 60 can be downsized.

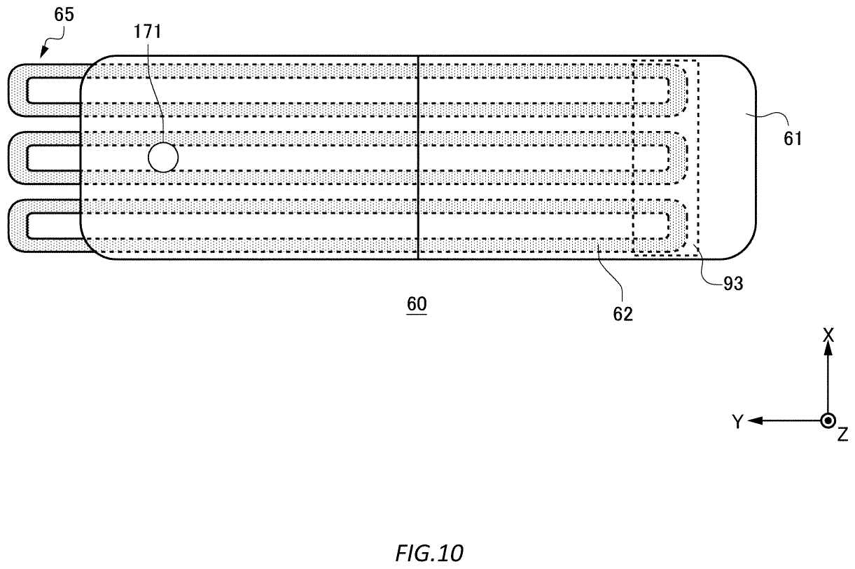

FIG. 10 illustrates an example of a top view of the resistance adjustment portion 60. As an example, FIG. 10 is a top view of the resistance adjustment portion 60 illustrated in FIG. 9A. Since the resistance portion 62 is provided below the diode element portion 61, the resistance portion 62 is invisible in top view, but in FIG. 10, a part provided below the diode element portion 61 is indicated by a dotted line in order to grasp a positional relationship. The resistance adjustment portion 60 in the present example includes the resistance adjustment trench portion 65 which is provided to extend in the predetermined direction in the semiconductor substrate 10. The resistance portion 62 is provided in the resistance adjustment trench portion 65 in the present example.

The resistance adjustment trench portion 65 in the present example is provided to extend in the Y axis direction. That is, the resistance adjustment trench portion 65 in the present example is provided to extend in a rectification direction of the diode element portion 61, but is not limited thereto. The resistance adjustment trench portion 65 may be provided to extend in the X axis direction.

A plurality of the resistance adjustment trench portions 65 may be provided. The resistance adjustment portion 60 in the present example includes six resistance adjustment trench portions 65. An end portion of the resistance adjustment trench portion 65 in the present example has a U shape on the front surface 21 of the semiconductor substrate 10, similarly to the gate trench portion 40. That is, the resistance adjustment trench portion 65 may include two extending parts extending along the extending direction and a connecting part connecting the two extending parts.

A length of the resistance adjustment trench portion 65 in a predetermined direction may be shorter than a length of the gate trench portion 40 in the current sensing portion 90. The length of the resistance adjustment trench portion 65 may be 2 μm or more and 2000 μm or less. In addition, the length of the resistance adjustment trench portion 65 may be 50 μm or more and 500 μm or less. By adjusting the length of the resistance adjustment trench portion 65, the resistance value of the resistance adjustment portion 60 can be adjusted.

The resistance adjustment trench portion 65 may be provided in a shape in which a plurality of U-shaped trenches are connected. The resistance adjustment trench portion 65 may include n extending parts (n is a natural number of 2 or more) extending along the extending direction and n-1 connecting part(s) each connecting two extending parts. With such a shape, the resistance value of the resistance adjustment portion 60 can be easily adjusted.

The semiconductor device 100 in the present example may include both the resistance adjustment portion 60 including the resistance adjustment trench portion 65 and the resistance adjustment portion 60 not including the resistance adjustment trench portion 65. That is, the main adjustment portion 160 may include the resistance adjustment trench portion 65, and the sense adjustment portion 260 may not include the resistance adjustment trench portion 65. Alternatively, the main adjustment portion 160 may not include the resistance adjustment trench portion 65, and the sense adjustment portion 260 may include the resistance adjustment trench portion 65.

While the present invention has been described by way of the embodiments, the technical scope of the present invention is not limited to the above-described embodiments. It is apparent to persons skilled in the art that various alterations or improvements can be made to the above described embodiments. It is also apparent from the described scope of the claims that the embodiments to which such alterations or improvements are made can be included in the technical scope of the present invention. For example, in the resistance adjustment portion 60, the resistance portion 62 may be arranged on the gate pad 150 side of the diode element portion 61.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, the specification, or the drawings for the sake of convenience, it does not necessarily mean that the process must be performed in this order.

### Explanation of References

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 32: dummy dielectric film; 34: dummy conductive portion; 38: interlayer dielectric film; 40: gate trench portion; 41: extending part; 42: gate dielectric film; 43: connecting part; 44: gate conductive portion; 52: emitter electrode; 53: contact hole; 54: contact hole; 55: contact hole; 56: contact hole; 57: contact hole; 60: resistance adjustment portion; 61: diode element portion; 62: resistance portion; 63: resistance region; 64: resistance adjustment dielectric film; 65: resistance adjustment trench portion; 70: transistor portion; 71: mesa portion; 81: first insulating portion; 82: second insulating portion; 83: third insulating portion; 90: current sensing portion; 91: first polysilicon layer; 92: second polysilicon layer; 93: interface; 100: semiconductor device; 102:

end side; 104: active portion; 106: outer peripheral portion; 110: front surface side metal layer;

120: back surface side lifetime control region; 130: anode pad; 132: anode wiring; 140: cathode pad; 142: cathode wiring; 150: gate pad; 152: gate metal wiring; 160: main adjustment portion; 161: main on-side diode; 162: main off-side diode; 166: main on-side resistor; 167: main off-side resistor; 171: first contact portion; 172: second contact portion; 173: third contact portion; 180: temperature sensing portion; 190: current sense pad; 194: gate conductive portion; 260: sense adjustment portion; 261: sense on-side diode; 262: sense off-side diode; 266: sense on-side resistor; 267: sense off-side resistor; 271: first opening; 272: second opening; 273: third opening; 361: cathode region; and 362: anode region.

What is claimed is:

1. A semiconductor device comprising:
a transistor portion;
a current sensing portion which detects a current flowing through the transistor portion;
a gate pad which is provided above a semiconductor substrate; and
a resistance adjustment portion which is electrically connected to the gate pad and adjusts gate resistances of the transistor portion and the current sensing portion, wherein
the resistance adjustment portion includes
a main adjustment portion which is electrically connected to a gate conductive portion of the transistor portion, and
a sense adjustment portion which is electrically connected to a gate conductive portion of the current sensing portion, and
each of the main adjustment portion and the sense adjustment portion includes a diode element portion including a plurality of diodes provided in anti-parallel and a resistance portion which is connected to the diode element portion.

2. The semiconductor device according to claim 1, wherein
the resistance portion has a resistance value such that the transistor portion is turned on before the current sensing portion, and the transistor portion is turned off later than the current sensing portion.

3. The semiconductor device according to claim 1, wherein
the main adjustment portion includes
a main on-side diode which has an anode electrically connected to the gate pad and a cathode electrically connected to the gate conductive portion of the transistor portion,
a main off-side diode which has an anode electrically connected to the gate conductive portion of the transistor portion and a cathode electrically connected to the gate pad, and
a main off-side resistor which is electrically connected between the anode of the main off-side diode and the gate conductive portion of the transistor portion.

4. The semiconductor device according to claim 1, wherein
the sense adjustment portion includes
a sense on-side diode which has an anode electrically connected to the gate pad and a cathode electrically connected to the gate conductive portion of the current sensing portion,
a sense off-side diode which has an anode electrically connected to the gate conductive portion of the current sensing portion and a cathode electrically connected to the gate pad, and
a sense on-side resistor which is electrically connected between the cathode of the sense on-side diode and the gate conductive portion of the current sensing portion.

5. The semiconductor device according to claim 1, wherein
the main adjustment portion includes
a main on-side diode which has an anode electrically connected to the gate pad and a cathode electrically connected to the gate conductive portion of the transistor portion,
a main off-side diode which has an anode electrically connected to the gate conductive portion of the transistor portion and a cathode electrically connected to the gate pad,
a main on-side resistor which is electrically connected between the cathode of the main on-side diode and the gate conductive portion of the transistor portion, and
a main off-side resistor which is electrically connected between the anode of the main off-side diode and the gate conductive portion of the transistor portion.

6. The semiconductor device according to claim 5, wherein
the sense adjustment portion includes
a sense on-side diode which has an anode electrically connected to the gate pad and a cathode electrically connected to the gate conductive portion of the current sensing portion,
a sense off-side diode which has an anode electrically connected to the gate conductive portion of the current sensing portion and a cathode electrically connected to the gate pad,
a sense on-side resistor which is electrically connected between the cathode of the sense on-side diode and the gate conductive portion of the current sensing portion, and
a sense off-side resistor which is electrically connected between the anode of the sense off-side diode and the gate conductive portion of the current sensing portion.

7. The semiconductor device according to claim 1, wherein
in the resistance adjustment portion, the diode element portion is provided above the resistance portion.

8. The semiconductor device according to claim 7, comprising:
a first insulating portion which is provided above the semiconductor substrate;
a second insulating portion which is provided above the first insulating portion;
an interlayer dielectric film which is provided above the first insulating portion and the second insulating portion; and
a front surface side metal layer which is provided on the interlayer dielectric film, wherein
the resistance portion is provided on the first insulating portion, and
the diode element portion is provided above the resistance portion with the second insulating portion interposed therebetween.

9. The semiconductor device according to claim 8, comprising
a first contact portion which is provided to extend from an upper end of the interlayer dielectric film to an upper end of the first insulating portion through the diode element portion, the second insulating portion, and the resistance portion, and connects the front surface side metal layer and the diode element portion.

10. The semiconductor device according to claim 9, comprising
a third insulating portion which is provided around the first contact portion and electrically separates the first contact portion from the resistance portion.

11. The semiconductor device according to claim 8, comprising
a second contact portion which is provided to extend from an upper end of the interlayer dielectric film to an upper end of the first insulating portion through the diode element portion, the second insulating portion, and the resistance portion, and connects the front surface side metal layer and the resistance portion.

12. The semiconductor device according to claim 1, wherein
the resistance adjustment portion includes a resistance adjustment trench portion, which is provided to extend in a predetermined direction, in the semiconductor substrate, and
the resistance portion is provided in the resistance adjustment trench portion.

13. The semiconductor device according to claim 8, wherein
the diode element portion and the resistance portion are in direct contact with each other via a contact hole provided in the second insulating portion.

14. The semiconductor device according to claim 1, wherein
the resistance adjustment portion includes
a resistance adjustment trench portion, which is provided to extend in a predetermined direction, in the semiconductor substrate,
a first polysilicon layer which is provided inside the resistance adjustment trench portion, and
a second polysilicon layer which is provided in direct contact with the first polysilicon layer.

15. The semiconductor device according to claim 1, wherein
the resistance adjustment portion includes a resistance adjustment trench portion, which is provided to extend in a predetermined direction, in the semiconductor substrate,
the diode element portion includes a cathode region and an anode region, and
at least one of the cathode region or the anode region is provided in the resistance adjustment trench portion.

16. The semiconductor device according to claim 1, wherein
a thickness of the resistance portion is smaller than a thickness of the diode element portion.

17. A method for manufacturing a semiconductor device including a transistor portion and a current sensing portion, the method comprising:
providing a gate pad above a semiconductor substrate; and
providing a resistance adjustment portion which is electrically connected to the gate pad and adjusts gate resistances of the transistor portion and the current sensing portion, wherein
the providing the resistance adjustment portion includes
forming a main adjustment portion which is electrically connected to a gate conductive portion of the transistor portion, and
forming a sense adjustment portion which is electrically connected to a gate conductive portion of the current sensing portion, and
each of the main adjustment portion and the sense adjustment portion includes a diode element portion including a plurality of diodes provided in anti-parallel and a resistance portion which is connected to the diode element portion.

18. The method for manufacturing the semiconductor device according to claim 17, the method comprising:
forming a first insulating portion above the semiconductor substrate;
forming a first polysilicon layer for forming the resistance portion on the first insulating portion;
forming a second insulating portion on the first polysilicon layer;
forming a second polysilicon layer for forming the diode element portion on the second insulating portion;
forming an interlayer dielectric film above the diode element portion and the resistance portion;
forming a first opening, which is for forming a first contact portion, to penetrate the interlayer dielectric film, the second polysilicon layer, and the second insulating portion;
forming a second opening, which is for forming a second contact portion, to penetrate the interlayer dielectric film, the second polysilicon layer, the second insulating portion, and the first polysilicon layer;
forming the first contact portion in the first opening; and
forming the second contact portion in the second opening.

19. The method for manufacturing the semiconductor device according to claim 18, wherein
the first opening and the second opening are formed by a same etching process, and
the first contact portion and the second contact portion are formed by a same contact forming process.

20. The method for manufacturing a semiconductor device according to claim 17, the method comprising:
forming a first insulating portion above the semiconductor substrate;
forming a first polysilicon layer for forming the resistance portion on the first insulating portion;
forming a second insulating portion on the first polysilicon layer;
forming a second polysilicon layer for forming the diode element portion on the second insulating portion;
forming an interlayer dielectric film above the diode element portion and the resistance portion;
forming a first opening, which is for forming a first contact portion, to penetrate the interlayer dielectric film, the second polysilicon layer, and the second insulating portion; and
forming the first contact portion in the first opening.

21. The method for manufacturing the semiconductor device according to claim 18, the method comprising:
forming a third opening in the first polysilicon layer before the forming the second insulating portion; and
forming a third insulating portion in the third opening, wherein
the forming the first opening includes forming the first opening to penetrate the third insulating portion, and
the forming the first contact portion includes forming the first contact portion inside the third insulating portion.
